(19) United States
(12) Patent Application Publication
(10) Pub. No.: US 2023/0244512 A1
(43) Pub. Date: Aug. 3, 2023

(54) FAST WAVEFORM CAPTURE WITH LOW HARDWARE FOOTPRINT ENABLING FULL VISIBILITY

(71) Applicant: Synopsys, Inc., Mountain View, CA (US)

(72) Inventors: Olivier Sallenave, Lagarrigue (FR); Jeremy Ozog, Velizy-Villacoublay (FR); Olivier Coudert, Sunnyvale, CA (US); Thiago Martins, Bourg-la-Reine (FR); Cedric Thepenier, Montrouge (FR)

(21) Appl. No.: 18/102,371

(22) Filed: Jan. 27, 2023

Related U.S. Application Data
(60) Provisional application No. 63/304,469, filed on Jan. 28, 2022.

(51) Int. Cl. G06F 9/455

(52) U.S. Cl. CPC G06F 9/455

(57) ABSTRACT

A method of generating waveforms of a circuit design in a hardware emulation system, includes, capturing, using a first block of the system, input signals at each k*d emulation cycle, wherein k and d are integers and k≥0 and d>0; capturing, using the first logic block at each (k*d+i) cycle, value of each input signal determined to have changed relative to a previous emulation cycle, wherein 0<i<d; capturing, using a second logic block, outputs of sequential elements at each k*w*d emulation cycle, wherein w is an integer greater than zero; capturing, using the second logic block, at each (k*w*d+j*d) emulation cycle, outputs of each sequential element that is determined to have changed relative to cycle (k*w*d+(j−1)*d), wherein j is an integer and wherein 0<j<w; and generating waveforms for the signals based on the captured input signals and captured values of the sequential elements.

### RELATED APPLICATION

The present application claims benefit under 35 USC 119(e) of U.S. Patent Application No. 63/304,469 filed Jan. 28, 2022, the content of which is incorporated herein by reference in its entirety.

### TECHNICAL FIELD

The present disclosure relates to verification of integrated circuits (IC), and more particularly, to signal capture and waveform generation during the netlist verification of a circuit using a hardware emulation system.

### BACKGROUND

Prior to manufacturing an IC, the IC netlist is verified using a software simulation and/or a hardware emulation system. A hardware emulation system often includes a multitude of programmable logic devices, such as field programmable gate arrays (FPGAs), to which the various components of a circuit design are mapped.

Typical netlist verification methods that provide full visibility on (i.e., accessibility to) a design under test (DUT) adversely impact either the emulation hardware capacity or the runtime frequency, thereby affecting the debug methodology and slowing down the netlist verification process.

### SUMMARY

A method of generating waveforms associated with signals of a circuit design in a hardware emulation system, in accordance with one embodiment of the present disclosure, includes, in part, capturing, using at least a first logic block disposed in the hardware emulation system, values of input signals of the circuit design at each k*d emulation cycle, wherein k and d are integers and wherein k≥0 and d>0; capturing, using the at least first logic block and at each (k*d+i) emulation cycle, value of each input signal whose value is determined to have changed relative to the signal's value at a previous emulation cycle, wherein 0<i<d; capturing, using at least a second logic block disposed in the hardware emulation system, output values of a multitude of sequential elements of the circuit design at each k*w*d emulation cycle, wherein w is an integer greater than zero; capturing, using the at least second logic block and at each (k*w*d+j*d) emulation cycle, output value of each sequential element that is determined to have changed relative to the sequential element's output value at cycle (k*w*d+(j−1)*d), wherein j is an integer and wherein 0<j<w; and generating, by a processing device, waveforms for the signals of the circuit design based on the captured values of the input signals and captured values of the plurality of sequential elements.

In one embodiment, the method further includes, in part, varying one or more of d and w during the hardware emulation. In one embodiment, the addresses associated with the input signals and the multitude of sequential elements are defined by a compiler of the hardware emulation system. In one embodiment, the values of the input signals and the values of outputs of the multitude of sequential elements are streamed by a runtime software executed by a computer coupled to the hardware emulation system.

In one embodiment, the first logic block and the second logic block are logic blocks of one or more field programmable gate arrays (FPGAs) disposed in the hardware emulation system. In one embodiment, the runtime software generates a first thread for capturing the input signals, and a second thread for capturing the output values of the multitude of sequential elements. In one embodiment, the synchronization between the first thread and the second thread is achieved by a clock signal controlled by the second thread. In one embodiment, w has a same value as the register width of a processing unit performing the computer simulation.

A non-transitory computer readable medium, in accordance with one embodiment of the present disclosure, includes stored instructions, which when executed by a processor, cause the processor to: receive a netlist of a logic circuit design; program a hardware emulation system in accordance with the received netlist; apply a testbench to the logic circuit design programmed in the hardware emulation system; spawn, at an emulation runtime, a first thread dedicated to capturing output values of a multitude of sequential elements associated with the circuit design; spawn, at the emulation runtime, a second thread dedicated to capturing a multitude of input signal values associated with the circuit design; synchronize the first and second threads using a clock signal controlled by the first thread; store the captured values of the multitude of sequential elements and input signals using the clock signal; and generate a multitude of waveforms associated with the logic circuit design using the stored values.

In one embodiment, the stored instructions further cause the processor to vary, during the emulation, cycles during which the multitude of input signals are captured. In one embodiment, the stored instructions further cause the processor to vary, during the emulation, cycles during which the output signals of the multitude of sequential elements are captured.

In one embodiment, the stored instructions further cause the processor to capture values of input signals of the circuit design at each k*d emulation cycle, wherein k and d are integers and wherein k≥0 and d>0; capture values of each input signal whose value is determined to have changed at each (k*d+i) emulation cycle relative to the signal's value at a previous emulation cycle wherein 0<i<d; capture output values of the multitude of sequential elements of the circuit design at each k*w*d emulation cycle, wherein w is an integer greater than zero; and capture at each (k*w*d+j*d) emulation cycle, output value of each sequential element that is determined to have changed relative to the sequential element's output value at cycle (k*w*d+(j−1)*d), wherein j is an integer and wherein 0<j<w.

A hardware emulation system, in accordance with one embodiment of the present disclosure, includes, in part, a memory storing instructions; and a processor, coupled with the memory and configured to execute the instructions. The instructions when executed, cause the processor to: capture, using at least a first logic block disposed in the hardware emulation system, values of input signals of the circuit design at each k*d emulation cycle, wherein k and d are integers, and wherein k≥0 and d>0; capture, using the at least first logic block and at each (k*d+i) emulation cycle, values of each input signal whose value is determined to have changed relative to the signal's value at a previous emulation cycle wherein 0<i<d; capture, using at least a second logic block disposed in the hardware emulation system, output values of the multitude of sequential elements of the circuit design at each k*w*d emulation cycle, wherein w is an integer greater than zero; capture, using the at least second logic block and at each (k*w*d+j*d) emulation cycle, output value of each sequential element that is determined to have changed relative to the sequential element's output value at cycle (k*w*d+(i−1)*d), wherein j is an integer and wherein 0<j<w; and invoke a computer simulation using the captured values of the input signals and captured values of the multitude of sequential elements to generate waveforms for the signals of the circuit design.

In one embodiment, the instruction further cause the processor to vary d and w during the hardware emulation. In one embodiment, the instruction further cause the processor to invoke a compiler of the hardware emulation system to define addresses associated with the input signals and the multitude of sequential elements. In one embodiment, the instruction further cause the processor to invoke a runtime software of the hardware emulation system to stream values of the input signals and the values of outputs of the multitude of sequential elements.

In one embodiment, the first logic block and the second logic block are logic blocks of one or more field programmable gate arrays (FPGAs) disposed in the hardware emulation system. In one embodiment, the instruction further cause the processor to invoke the runtime software to generate a first thread for capturing the input signals, and a second thread for capturing the output values of the plurality of sequential elements. In one embodiment, the instruction further cause the processor to achieve synchronization between the first thread and the second thread via a clock signal controlled by the second thread. In one embodiment, w has a same value as the register width of a processor unit performing the computer simulation.

### BRIEF DESCRIPTION OF THE DRAWINGS

The disclosure will be understood more fully from the detailed description given below and from the accompanying figures of embodiments of the disclosure. The figures are used to provide knowledge and understanding of embodiments of the disclosure and do not limit the scope of the disclosure to these specific embodiments. Furthermore, the figures are not necessarily drawn to scale.

FIG. 1 shows a multitude of cycles during which frames associated with primary signals and sequential element signals of a circuit design undergoing hardware emulation are captured, in accordance with one embodiment of the present disclosure.

FIG. 2 is a flowchart showing the splitting of the signals to be captured into two groups, in accordance with one embodiment of the present disclosure.

FIG. 3 is a flowchart for generating waveforms using a hardware emulation system, in accordance with one embodiment of the present disclosure.

FIG. 4 is a flowchart for supplying signals to be debugged, in accordance with one embodiment of the present disclosure.

FIG. 5 is a flowchart showing synchronization between different threads operating to capture signals to be debugged, in accordance with one embodiment of the present disclosure.

FIG. 6 shows various activities performed by the threads shown in FIG. 5, in accordance with one embodiment of the present disclosure.

FIG. 7 shows logic blocks configured to receive signals from a circuit design, in accordance with one embodiment of the present disclosure.

FIG. 8 shows signals being captured from a circuit design programmed into a hardware emulation system, in accordance with one embodiment of the present disclosure.

FIG. 9 depicts a flowchart of various processes used during the design and manufacture of an integrated circuit in accordance with some embodiments of the present disclosure.

FIG. 10 shows a diagram of an example of an emulation system in accordance with some embodiments of the present disclosure.

FIG. 11 depicts an example of a diagram a computer system in which embodiments of the present disclosure may operate.

### DETAILED DESCRIPTION

Aspects of the present disclosure relates to fast waveform capture with low hardware footprint using periodic readback capture and contiguous capture of primary signals.

In verifying the netlist of a logic circuit design using a hardware emulation system, existing techniques suffer from a number of shortcomings, such as emulation hardware capacity and runtime frequency. Such shortcomings affect the debugging methodology and slow down the netlist verification process.

In accordance with one aspect of the present disclosure, a hardware emulation system is configured to verify the netlist of a logic circuit design.

Among technical advantages of the present disclosure are the use of a relatively small number of hardware components of a hardware emulation system, a relatively fast netlist compilation, as well as a relatively high emulation speed during the netlist verification of a logic circuit design.

Definitions

Where used, S represents the set of signals in a logic circuit design or device under test, abbreviated herein as DUT.

Where used, v(s,t) represents the value of signal s at clock cycle t. A value change is a triplet <s, t, v>, where v is the value of the signal s at cycle t.

Where used, the primary inputs to a DUT represent the signals received by the DUT and therefore cannot be reconstructed. The set of primaries P represent the signals of the design that are not reconstructed. It contains the primary inputs of the design, as well as the outputs of memory blocks and other blocks whose internal connections are not known. Accordingly, using set theory notation: P⊂S.

Where used, E represents the set of sequential elements, i.e., flip-flops and latches: E⊂S and P∩E=∅.

Where used, C represents the union of the primary signals and sequential element signals:

### C⊂S. Therefore C=P∪E.

Where used, a full frame at cycle t represents the values of all signals in C at a given clock cycle t, i.e.: {<s, t, v>|s∈C}.

Where used, a delta full frame represents all value changes within C at cycle t with respect to the values of C at cycle t−d:

{<s, t, v>|s∈C, v≠v(s, t−d)}, where d is an integer greater than 0.

Where used, a delta sequential frame represents all value changes within sequential elements at cycle t with respect to the values of C at cycle t−d:

{<s, t, v>|s∈E, v≠v(s, t−d)}.

Where used, a delta primary frame represents all value changes within primary signals at cycle t with respect to the value of primary signals at cycle t−1:

{<s, t, v>|s∈P, v≠v(s, t−1)}.

Where used, the term interval size represents the number of clock cycles d between two full frames, including delta full frames.

Where used, the term window size represents the number of clock cycles w between two full frames, excluding delta full frames.

Knowing the values of signals C at cycle t, the value of signal s in (S−C) (i.e., a combinational signal), i.e., v(s, t) may be reconstructed using simulation.

Knowing the values of signals in Pat cycle t and t−1, as well as the values of signals in set E at t−1, the values of signals (i.e., v(s, t)) in set E may be reconstructed using sequential simulation.

Accessibility to signals in a circuit design programmed into a hardware emulation system may be achieved using an instrumentation-based capture (IBC) technique or a readback capture technique. In accordance with the IBC technique (alternatively referred to herein as IBC), a subset of the signal to be captured (i.e., sampled) is specified by the user before compiling the design. The compiler then configures one or more logic blocks on the FPGAs disposed in a hardware emulation system to receive and process the specified signals. The IBC technique typically uses significant hardware resources (e.g., 30%-40%) of the emulation system for the instrumentation. The IBC technique, however, has a relatively small impact on the emulation frequency.

In accordance with another technique, referred to herein as the readback (RB) technique, the FPGAs are configured to read the values of the FPGA registers specified before or during the emulation. The register output values are subsequently used to reconstruct the selected signal values using computer simulations. Therefore, in accordance with the RB technique (alternatively referred to herein as RB), runtime software (i) configures the FPGAs so that the FPGAs can read their register values, (ii) controls the clocks during emulation, and (iii) captures the register values during different clock cycles. Computer simulations are then performed using combinational logic to reconstruct the values of the selected signals. The RB technique does not require additional hardware but can significantly decrease the emulation frequency (e.g., by a factor of 1000).

In accordance with embodiments of the present disclosure (i) primary input signals of a circuit design or device under test (DUT) are captured using the IBC technique; (ii) output values of the registers of the DUT are captured using the RB technique; and (iii) computer simulations are performed to reconstruct the DUT signal waveforms.

In accordance with one embodiment, the IBC technique is used to capture full primary frames of a logic circuit design undergoing emulation in each (k*d) cycle, where k is an arbitrary integer greater than or equal to zero, and where d, which is also an arbitrary integer greater than zero, refers to an interval between two consecutive full primary frames. In such embodiments, delta primary frames are captured at intervals (k*d+i), where i is the emulation cycle varying between 0<i<d. Because delta primary frames include only primary signal value changes with respect to their values in a previous cycle, less data is transferred from the emulation system for storage on a disk. Therefore, only a relatively small fraction of the circuit design is instrumented (e.g., 5-10% of the signals), thereby resulting in a negligible overhead in hardware capacity usage.

The values of output signals of sequential elements are captured using the RB technique. In one embodiment, full sequential frames are captured every (k*w*d) cycles, where w is an arbitrary integer greater than zero and such that the product (w*d) defines a window size between two successive full sequential frames. Delta sequential frames are captured every (k*w*d+j*d) cycle, where 0<j<w .

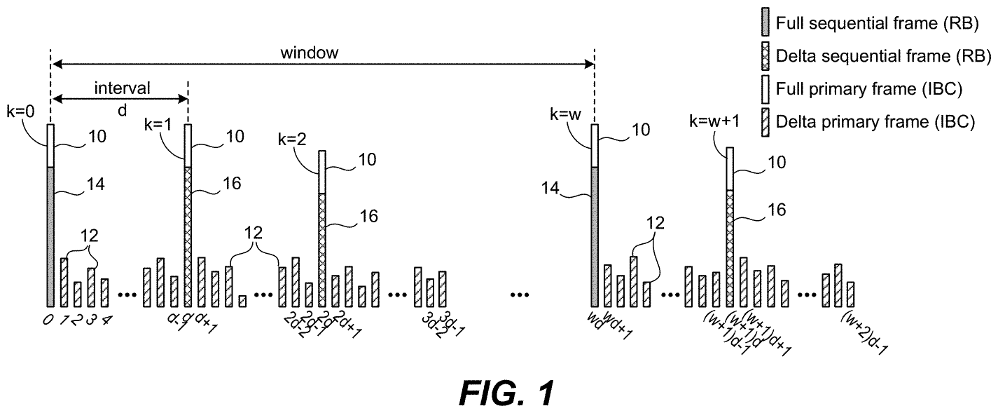

FIG. 1 shows an example of a multitude of cycles during which frames associated with primary signals and sequential element output signals are captured, in accordance with one embodiment of the present disclosure. Full primary frames 10 are shown as being captured using the IBC technique at each (k*d) cycle, where k is shown as varying from 0 to (w+1) in FIG. 1. Delta primary frames 12 are shown as being captured using the IBC technique at each (k*d+i) cycle, where i is the emulation cycle shown as varying between 0<i<d in FIG. 1.

Full sequential frames 14 are shown as being captured using the RB technique at each (k*w*d) cycle, where w is an arbitrary integer. Delta sequential frames 16 are shown as being captured using the RB technique at each (k*w*d+j*d) cycle, where j is an integer varying between 0<j<w. Computer simulations of the frames received via the RB technique may be performed in parallel to reconstruct the waveform of the DUT for all intervals of a window. Both d and w are arbitrary values that may be changed during the emulation runtime. In one embodiment, if the central processing unit controlling the waveform reconstruction has registers that are 128 bits wide, then w may be selected to have a value 128. When using the IBC technique, the sets of signals to be captured are defined in a description file before compiling the design. The compiler instruments the signals, as defined in the description file, and connects them to the logic block configured to receive and stream the captured signal values.

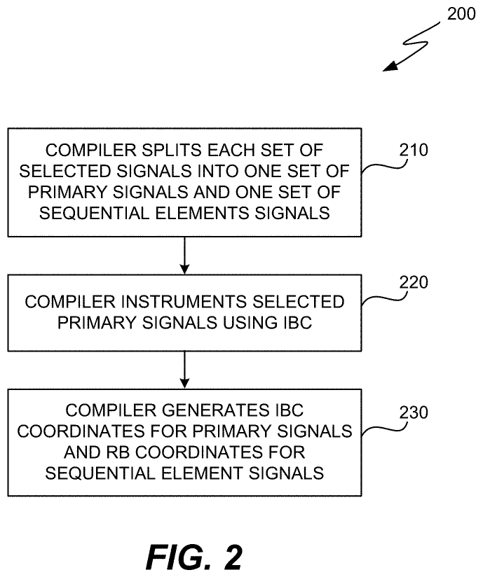

FIG. 2 is a process flow diagram 200 showing the splitting of the signals to be captured into two distinct groups during the compilation. At 210, the compiler splits the design signals to be captured into a set of primary signal and a set of sequential element signals. At 220, the compiler instruments the primary signals using the IBC technique. At 230, the compiler generates the coordinates (i.e., addresses) for the primary signals to be captured using the IBC technique, and the coordinates for the sequential element signals to be captured using the RB technique. As described above, in the IBC technique, a subset of the signal to be captured is specified by the user before compiling the design.

The compiler then configures one or more logic blocks on the FPGAs disposed in a hardware emulation system to receive and process the specified signals. In the RB technique, the FPGAs are configured to read the values of the FPGA registers specified before or during the emulation. The register output values are subsequently used to reconstruct the selected signal values using computer simulations.

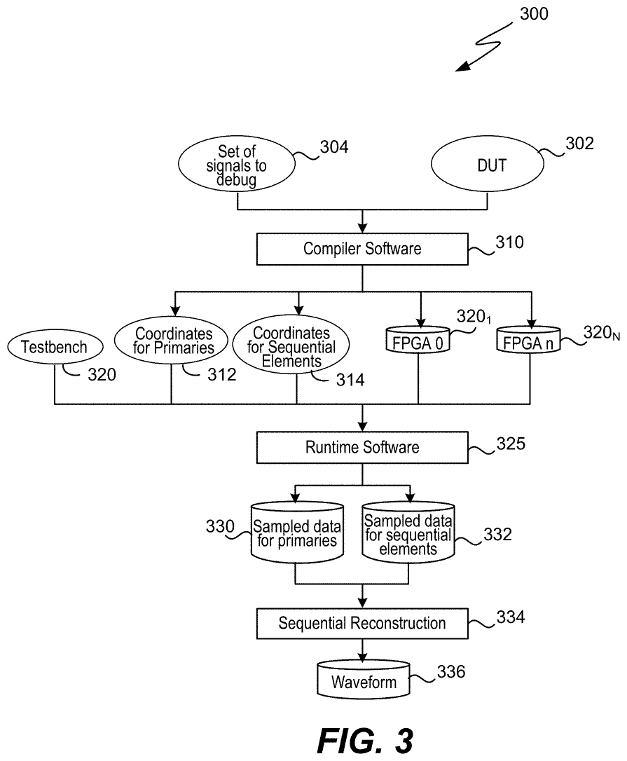

FIG. 3 is a process flow 300 for generating and capturing waveforms using a hardware emulation system, in accordance with one embodiment of the present disclosure. The netlist for DUT 302 and the set of signals 304 of the DUT to be captured and debugged are supplied to the compiler at 310. The compiler instruments the primary signals (i.e., routes the primary signals to the FPGA logic blocks configured to receive the primary signals) and generates a database which includes the IBC coordinates for the primary signals at 312, and RB coordinates for sequential elements at 314.

The IBC coordinates for the signals in the primary frames define the index of the logic block configured to receive the primary frames as well as the bit index of the signals within the frame. The RB coordinates for sequential elements define the sequential frame index (also referred to herein as sector index), as well as the bit index of the signals within the sequential frame.

The compiler configures the FGPAs at 320₁, 320₂ . . . 320_{N} disposed in the emulation system in conformity with the received netlist of the DUT and applies the test bench at 320 to the configured FPGAs. Thereafter, the emulation system's runtime software runs the emulations at 325 to generate samples of the primary signals at 330, and samples of the sequential element output signals at 332. At 334, computer simulations are performed to reconstruct the sequential element signals. To achieve this, the netlist of the DUT that is emulated by the emulation system is also supplied to a logic circuit simulator. By supplying samples of the primary signals and samples of the sequential element output signals to the logic circuit simulator, the sequential logic simulator reconstructs the waveform of all the signals in the design. At 336, waveforms for the reconstructed sequential element signals are generated.

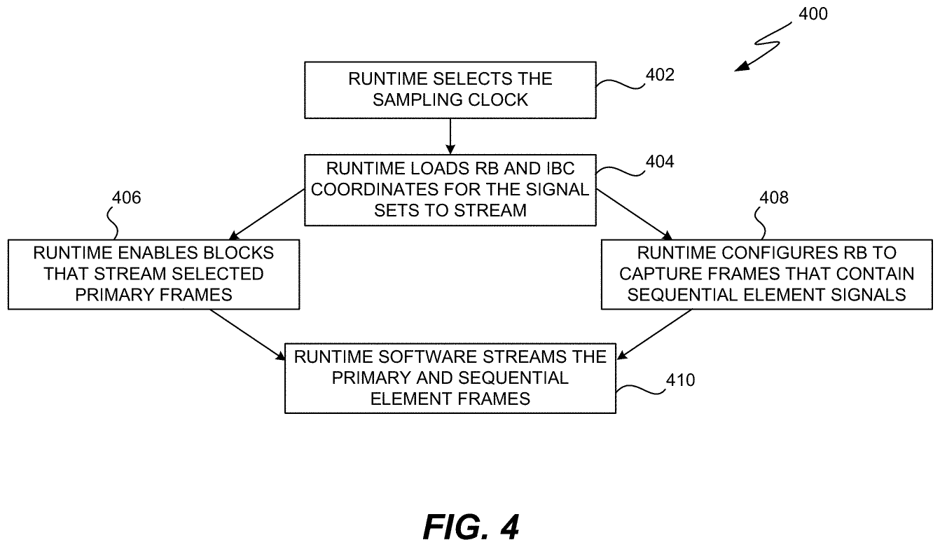

FIG. 4 is a flowchart 400 for supplying (also referred to herein as or streaming or dumping) signals to be debugged, in accordance with one embodiment of the present disclosure. At 402, a clock used for streaming the signals of the DUT is selected by the runtime software. At 404, the runtime software loads the IBC coordinates of the primary signals and RB coordinates of the sequential element signals that are to be streamed. At 406, the runtime software enables the configured logic blocks to stream the primary frames to the host computer of the emulation system executing the runtime software. At 408, the runtime software, using the RB coordinates of the sequential element signals, configures one or more FPGAs (or sectors of FPGAs) to capture frames of the sequential elements signals. At 410, the runtime software streams the received primary and sequential element frames.

In one embodiment, the runtime software performs the RB and IBC techniques using two different processing threads. The thread dedicated to the RB technique, referred to herein alternatively as the RB thread, performs, among other functions, clock control. The RB thread also captures sequential element signals in every d cycle of the selected sampling clock, as described above. When streaming delta sequential frames, the runtime software computes changes in the values of the sequential elements' signals with respect to the values of the same signals captured from the immediately previous cycle.

The thread dedicated to the IBC technique, referred to herein alternatively as the IBC thread, captures the primary signals using the configured logic block(s). At each (k*d) cycle, as described above with respect to FIG. 1, the runtime software instructs the configured logic block(s) to stream full primary frames. At each (k*d+i) cycle, as is also described above with respect to FIG. 1, the runtime software instructs the configured logic block(s) to stream delta primary frames.

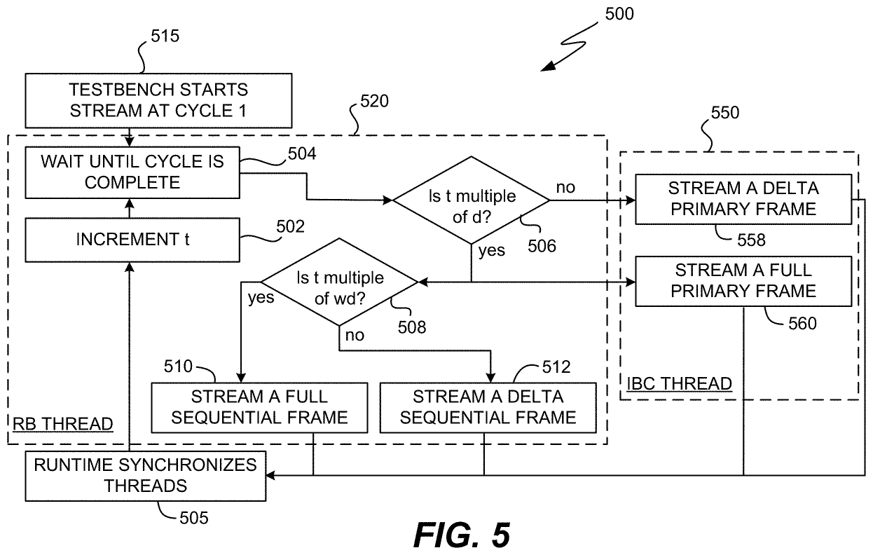

FIG. 5 is a flowchart 500 showing the synchronization of operations between the IBC and RB threads, in accordance with one embodiment of the present disclosure. Runtime software is shown at 505 as controlling the synchronization between IBC thread 550 and RB thread 520 when the test vectors are applied to the DUT at 515 by a testbench at emulation cycle t. As shown, steps 502, 504, 506, 508, 510 and 512 of flowchart 500 are performed by the RB thread 520, and steps 558 and 560 of flowchart 500 are performed by the IBC thread 550.

The runtime software increments the emulation cycle t by a count of one at 502 and waits for the cycle t emulation to complete at 504 using the testbench applied to the DUT during cycle t. If at 506, t is determined to be a multiple integer of d (d is an arbitrary integer defining cycles in which full primary frames of the design are captured as shown in FIG. 1), a full primary frame is streamed at 560. Additionally, if at 506, t is determined to be a multiple integer of d, and at 508, t is determined to be a multiple integer of w (w is the window size defining the cycles during which full sequential frames are streamed as shown in FIG. 1), then at 510, a full sequential frame is streamed. If at 506, t is determined to be a multiple integer of d, and at 508, t is determined not to be a multiple of integer of w, then at 512, a delta sequential frame is streamed. If at 506, t is determined not to be a multiple integer of d, then a delta primary frame is streamed at 558.

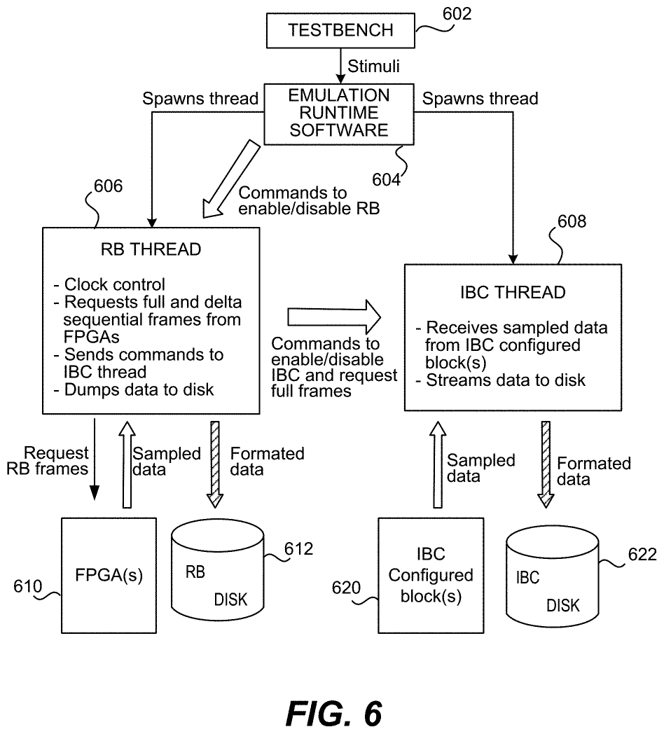

FIG. 6 shows the coordination of activities between the RB and IBC threads, in accordance with one embodiment of the present disclosure. In response to the stimuli provided by the testbench at 602, the emulation runtime software 604 spawns an RB thread 606 and an IBC thread 608. Commands to enable or disable the RB thread is issued by the emulation runtime software. The RB thread is shown at 606 as controlling the clock signals, requesting full and delta sequential frames from the FPGAs disposed in the emulator, sending commands to the IBC thread (such as commands to enable or disable the IBC thread), and streaming the data to a storage space, such as RB disk 612. The data streamed to RB disk 612 is provided in response to the request for sequential frames that, in turn, are sampled by one or more FPGAs 610 configured to provide the sampled data.

The IBC thread 608 is shown as receiving data associated with primary frames sampled by the FPGA logic blocks configured in accordance with the IBC technique, as described above, 620, and storing the received data in IBC disk 622. Command to enable/disable IBC thread 608 and request samples for full and delta primary frames are issued by RB thread 606. The RB thread notifies the IBC thread of each stream interval so that a full primary frame can be captured. The data that is captured by the RB and IBC threads may be written to disk 612 and 622, respectively, using a compression algorithm.

Controlling the clock signal in RB thread 606 may be achieved in a number of different ways. For example, in one embodiment, the configured logic block(s) may stop the clock signal and notify the runtime software accordingly. Once the data has been captured, the runtime software instructs the configured logic block(s) to resume the clock signal. In another embodiment, the runtime software may send commands to control the clock signals, including commands to resume the clock, stop the clock signal and poll the clock signal.

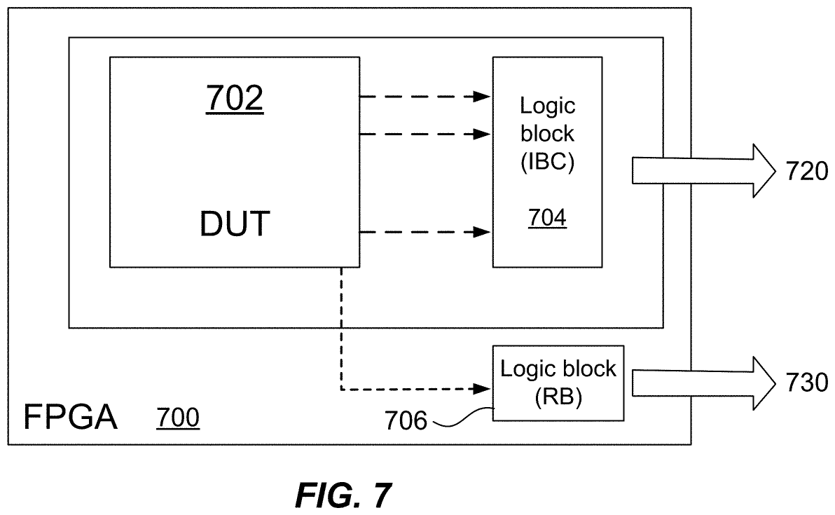

FIG. 7 shows a DUT 702 that has been programmed into one or more FPGAs 700 of an emulation system. Logic block 704 is configured by the compiler, in accordance with the IBC technique, to receive signals from DUT 704 and stream full primary frames and delta primary frames 720 in response. Logic block 704 may be a programmable hardware such as one or more programmable logic gates. Logic block 706, in accordance with the RB technique, accesses the registers of DUT 702 to generate full sequential frames and delta sequential frames 730. Logic block 706 may be a built-in logic circuitry configured to read or write signal from DUT 702.

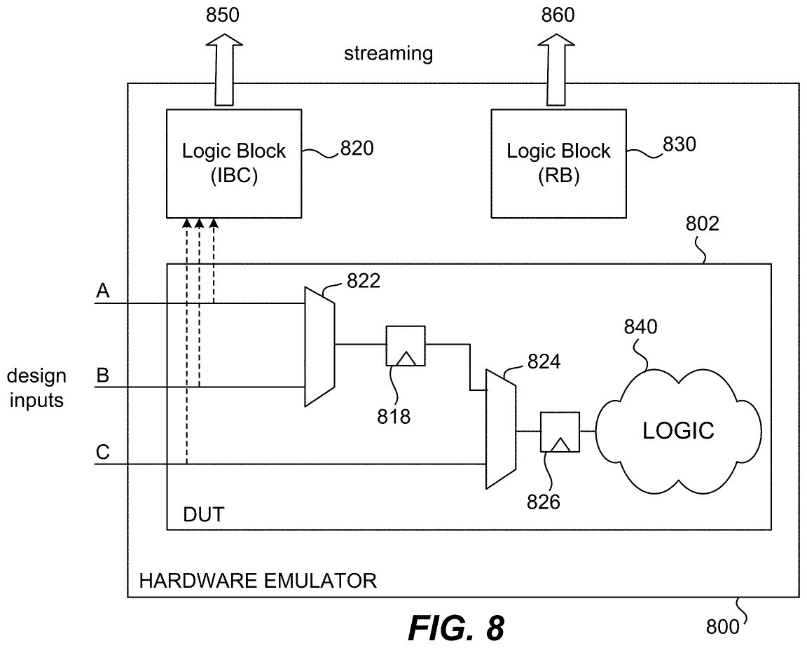

FIG. 8 shows a DUT 802 that has been programmed in hardware emulation system 800. DUT 802 is shown as including sequential elements 818, 826, multiplexers 822, 824 and a logic block 840. Input signals A, B are applied to multiplexer 822, and input signal C is applied to multiplexer 824. Input signals A, B and C are the primary signals and are also delivered to logic block 820 that is configured by the compiler, in accordance with the IBC technique, to stream full primary frames and delta primary frames 850. Output signals of sequential elements 818, 826, as well as output signals of sequential elements (not shown) disposed in logic block 840 are shown as being accessed by logic block 830 and streamed as full sequential frames and delta sequential frames 860. Logic block 830 is disposed in one or more FPGAs of the hardware emulation system 800 and is configured to access the output signals of the sequential elements in accordance with the RB technique.

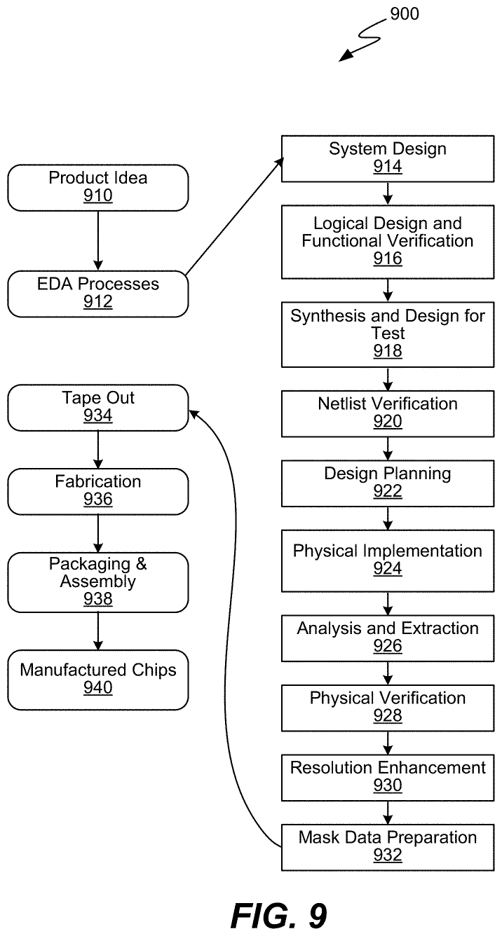

FIG. 9 illustrates an example set of processes 900 used during the design, verification, and fabrication of an article of manufacture such as an integrated circuit to transform and verify design data and instructions that represent the integrated circuit. Each of these processes can be structured and enabled as multiple modules or operations. The term ‘EDA’ signifies the term ‘Electronic Design Automation.’ These processes start with the creation of a product idea 910 with information supplied by a designer, information which is transformed to create an article of manufacture that uses a set of EDA processes 912. When the design is finalized, the design is taped-out 934, which is when artwork (e.g., geometric patterns) for the integrated circuit is sent to a fabrication facility to manufacture the mask set, which is then used to manufacture the integrated circuit. After tape-out, a semiconductor die is fabricated 936 and packaging and assembly processes 938 are performed to produce the finished integrated circuit 940.

Specifications for a circuit or electronic structure may range from low-level transistor material layouts to high-level description languages. A high-level description may be used to design circuits and systems, using a hardware description language (‘HDL’) such as VHDL, Verilog, SystemVerilog, SystemC, MyHDL or OpenVera. The HDL description can be transformed to a logic-level register transfer level (‘RTL’) description, a gate-level description, a layout-level description, or a mask-level description. Each lower level description adds more useful detail into the design description, for example, more details for the modules that include the description. The lower levels of description can be generated by a computer, derived from a design library, or created by another design automation process. An example of a specification language at a lower level language for specifying more detailed descriptions is SPICE, which is used for detailed descriptions of circuits with many analog components. Descriptions at each level is enabled for use by the corresponding tools of that layer (e.g., a formal verification tool). A design process may use a sequence depicted in FIG. 9. The processes described by be enabled by EDA products (or tools).

During system design 914, functionality of an integrated circuit to be manufactured is specified. The design may be optimized for desired characteristics such as power consumption, performance, area (physical and/or lines of code), and reduction of costs, etc. Partitioning of the design into different types of modules or components can occur at this stage.

During logic design and functional verification 916, modules or components in the circuit are specified in one or more description languages and the specification is checked for functional accuracy. For example, the components of the circuit may be verified to generate outputs that match the requirements of the specification of the circuit or system being designed. Functional verification may use simulators and other programs such as testbench generators, static HDL checkers, and formal verifiers. In some embodiments, special systems of components referred to as ‘emulators’ or ‘prototyping systems’ are used to speed up the functional verification.

During synthesis and design for test 918, HDL code is transformed to a netlist. In some embodiments, a netlist may be a graph structure where edges of the graph structure represent components of a circuit and where the nodes of the graph structure represent how the components are interconnected. Both the HDL code and the netlist are hierarchical articles of manufacture that can be used by an EDA product to verify that the integrated circuit, when manufactured, performs according to the specified design. The netlist can be optimized for a target semiconductor manufacturing technology. Additionally, the finished integrated circuit may be tested to verify that the integrated circuit satisfies the requirements of the specification.

During netlist verification 920, the netlist is checked for compliance with timing constraints and for correspondence with the HDL code. During design planning 922, an overall floor plan for the integrated circuit is constructed and analyzed for timing and top-level routing.

During layout or physical implementation 924, physical placement (positioning of circuit components such as transistors or capacitors) and routing (connection of the circuit components by multiple conductors) occurs, and the selection of cells from a library to enable specific logic functions can be performed. As used herein, the term ‘cell’ may specify a set of transistors, other components, and interconnections that provides a Boolean logic function (e.g., AND, OR, NOT, XOR) or a storage function (such as a flipflop or latch). As used herein, a circuit ‘block’ may refer to two or more cells. Both a cell and a circuit block can be referred to as a module or component and are enabled as both physical structures and in simulations. Parameters are specified for selected cells (based on ‘standard cells’) such as size and made accessible in a database for use by EDA products.

During analysis and extraction 926, the circuit function is verified at the layout level, which permits refinement of the layout design. During physical verification 928, the layout design is checked to ensure that manufacturing constraints are correct, such as DRC constraints, electrical constraints, lithographic constraints, and that circuitry function matches the HDL design specification. During resolution enhancement 930, the geometry of the layout is transformed to improve how the circuit design is manufactured.

During tape-out, data is created to be used (after lithographic enhancements are applied if appropriate) for production of lithography masks. During mask data preparation 932, the ‘tape-out’ data is used to produce lithography masks that are used to produce finished integrated circuits.

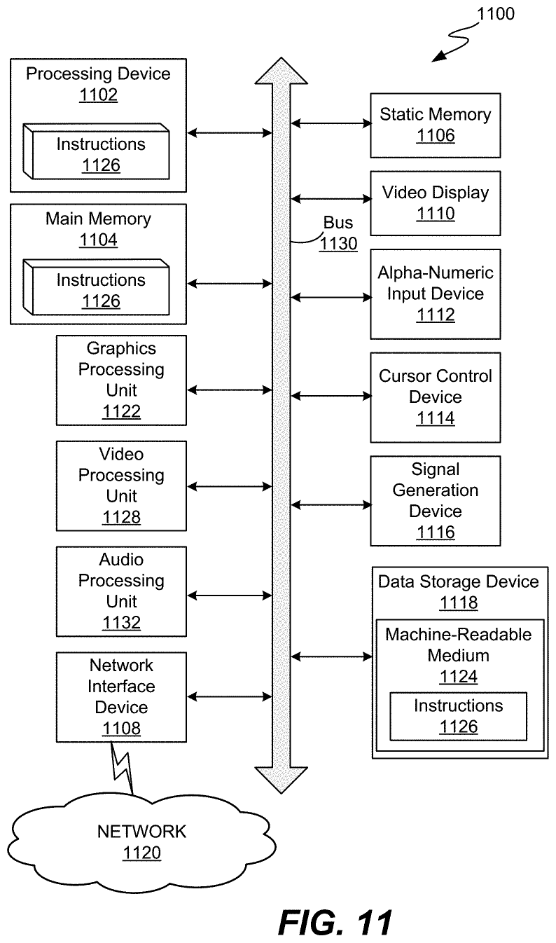

A storage subsystem of a computer system (such as computer system 1100 of FIG. 11) may be used to store the programs and data structures that are used by some or all of the EDA products described herein, and products used for development of cells for the library and for physical and logical design that use the library.

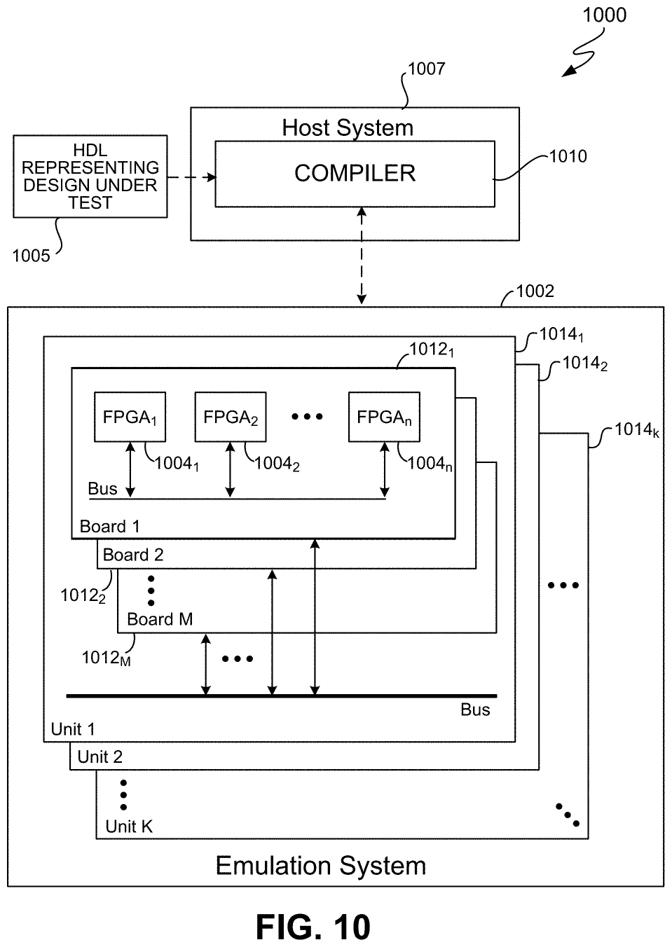

FIG. 10 depicts a diagram of an example emulation environment 1000. An emulation environment 1000 may be configured to verify the functionality of the circuit design. The emulation environment 1000 may include a host system 1007 (e.g., a computer that is part of an EDA system) and an emulation system 1002 (e.g., a set of programmable devices such as Field Programmable Gate Arrays (FPGAs) or processors). The host system generates data and information by using a compiler 1010 to structure the emulation system to emulate a circuit design. A circuit design to be emulated is also referred to as a Design Under Test (‘DUT’) where data and information from the emulation are used to verify the functionality of the DUT.

The host system 1007 may include one or more processors. In the embodiment where the host system includes multiple processors, the functions described herein as being performed by the host system can be distributed among the multiple processors. The host system 1007 may include a compiler 1010 to transform specifications written in a description language that represents a DUT and to produce data (e.g., binary data) and information that is used to structure the emulation system 1002 to emulate the DUT. The compiler 1010 can transform, change, restructure, add new functions to, and/or control the timing of the DUT.

The host system 1007 and emulation system 1002 exchange data and information using signals carried by an emulation connection. The connection can be, but is not limited to, one or more electrical cables such as cables with pin structures compatible with the Recommended Standard 232 (RS232) or universal serial bus (USB) protocols. The connection can be a wired communication medium or network such as a local area network or a wide area network such as the Internet. The connection can be a wireless communication medium or a network with one or more points of access using a wireless protocol such as BLUETOOTH or IEEE 802.11. The host system 1007 and emulation system 1002 can exchange data and information through a third device such as a network server.

The emulation system 1002 includes multiple FPGAs (or other modules) such as FPGAs 1004₁ and 1004₂ as well as additional FPGAs to 1004_{N}. Each FPGA can include one or more FPGA interfaces through which the FPGA is connected to other FPGAs (and potentially other emulation components) for the FPGAs to exchange signals. An FPGA interface can be referred to as an input/output pin or an FPGA pad. While an emulator may include FPGAs, embodiments of emulators can include other types of logic blocks instead of, or along with, the FPGAs for emulating DUTs. For example, the emulation system 1002 can include custom FPGAs, specialized ASICs for emulation or prototyping, memories, and input/output devices.

A programmable device can include an array of programmable logic blocks and a hierarchy of interconnections that can enable the programmable logic blocks to be interconnected according to the descriptions in the HDL code. Each of the programmable logic blocks can enable complex combinational functions or enable logic gates such as AND, and XOR logic blocks. In some embodiments, the logic blocks also can include memory elements/devices, which can be simple latches, flip-flops, or other blocks of memory. Depending on the length of the interconnections between different logic blocks, signals can arrive at input terminals of the logic blocks at different times and thus may be temporarily stored in the memory elements/devices.

FPGAs 1004₁ -1004_{N} may be placed onto one or more boards 1012₁ and 1012_{M}. Multiple boards can be placed into an emulation unit 1014₁. The boards within an emulation unit can be connected using the backplane of the emulation unit or any other types of connections. In addition, multiple emulation units (e.g., 1014₁ and 1014₂ through 1014_{K}) can be connected to each other by cables or any other means to form a multi-emulation unit system.

For a DUT that is to be emulated, the host system 1007 transmits one or more bit files to the emulation system 1002. The bit files may specify a description of the DUT and may further specify partitions of the DUT created by the host system 1007 with trace and injection logic, mappings of the partitions to the FPGAs of the emulator, and design constraints. Using the bit files, the emulator structures the FPGAs to perform the functions of the DUT. In some embodiments, one or more FPGAs of the emulators may have the trace and injection logic built into the silicon of the FPGA. In such an embodiment, the FPGAs may not be structured by the host system to emulate trace and injection logic.

The host system 1007 receives a description of a DUT that is to be emulated. In some embodiments, the DUT description is in a description language (e.g., a register transfer language (RTL)). In some embodiments, the DUT description is in netlist level files or a mix of netlist level files and HDL files. If part of the DUT description or the entire DUT description is in an HDL, then the host system can synthesize the DUT description to create a gate level netlist using the DUT description. A host system can use the netlist of the DUT to partition the DUT into multiple partitions where one or more of the partitions include trace and injection logic. The trace and injection logic traces interface signals that are exchanged via the interfaces of an FPGA. Additionally, the trace and injection logic can inject traced interface signals into the logic of the FPGA. The host system maps each partition to an FPGA of the emulator. In some embodiments, the trace and injection logic is included in select partitions for a group of FPGAs. The trace and injection logic can be built into one or more of the FPGAs of an emulator. The host system can synthesize multiplexers to be mapped into the FPGAs. The multiplexers can be used by the trace and injection logic to inject interface signals into the DUT logic.

The host system creates bit files describing each partition of the DUT and the mapping of the partitions to the FPGAs. For partitions in which trace and injection logic are included, the bit files also describe the logic that is included. The bit files can include place and route information and design constraints. The host system stores the bit files and information describing which FPGAs are to emulate each component of the DUT (e.g., to which FPGAs each component is mapped).

Upon request, the host system transmits the bit files to the emulator. The host system signals the emulator to start the emulation of the DUT. During emulation of the DUT or at the end of the emulation, the host system receives emulation results from the emulator through the emulation connection. Emulation results are data and information generated by the emulator during the emulation of the DUT which include interface signals and states of interface signals that have been traced by the trace and injection logic of each FPGA. The host system can store the emulation results and/or transmits the emulation results to another processing system.

After emulation of the DUT, a circuit designer can request to debug a component of the DUT. If such a request is made, the circuit designer can specify a time period of the emulation to debug. The host system identifies which FPGAs are emulating the component using the stored information. The host system retrieves stored interface signals associated with the time period and traced by the trace and injection logic of each identified FPGA. The host system signals the emulator to re-emulate the identified FPGAs. The host system transmits the retrieved interface signals to the emulator to re-emulate the component for the specified time period. The trace and injection logic of each identified FPGA injects its respective interface signals received from the host system into the logic of the DUT mapped to the FPGA. In case of multiple re-emulations of an FPGA, merging the results produces a full debug view.

The host system receives, from the emulation system, signals traced by logic of the identified FPGAs during the re-emulation of the component. The host system stores the signals received from the emulator. The signals traced during the re-emulation can have a higher sampling rate than the sampling rate during the initial emulation. For example, in the initial emulation a traced signal can include a saved state of the component every X milliseconds. However, in the re-emulation the traced signal can include a saved state every Y milliseconds where Y is less than X. If the circuit designer requests to view a waveform of a signal traced during the re-emulation, the host system can retrieve the stored signal and display a plot of the signal. For example, the host system can generate a waveform of the signal. Afterwards, the circuit designer can request to re-emulate the same component for a different time period or to re-emulate another component.

A host system 1007 and/or the compiler 1010 may include sub-systems such as, but not limited to, a design synthesizer sub-system, a mapping sub-system, a run time sub-system, a results sub-system, a debug sub-system, a waveform sub-system, and a storage sub-system. The sub-systems can be structured and enabled as individual or multiple modules or two or more may be structured as a module. Together these sub-systems structure the emulator and monitor the emulation results.

The design synthesizer sub-system transforms the HDL that is representing a DUT 1005 into gate level logic. For a DUT that is to be emulated, the design synthesizer sub-system receives a description of the DUT. If the description of the DUT is fully or partially in HDL (e.g., RTL or other levels of representation), the design synthesizer sub-system synthesizes the HDL of the DUT to create a gate-level netlist with a description of the DUT in terms of gate level logic.

The mapping sub-system partitions DUTs and maps the partitions into emulator FPGAs. The mapping sub-system partitions a DUT at the gate level into a number of partitions using the netlist of the DUT. For each partition, the mapping sub-system retrieves a gate level description of the trace and injection logic and adds the logic to the partition. As described above, the trace and injection logic included in a partition is used to trace signals exchanged via the interfaces of an FPGA to which the partition is mapped (trace interface signals). The trace and injection logic can be added to the DUT prior to the partitioning. For example, the trace and injection logic can be added by the design synthesizer sub-system prior to or after the synthesizing the HDL of the DUT.

In addition to including the trace and injection logic, the mapping sub-system can include additional tracing logic in a partition to trace the states of certain DUT components that are not traced by the trace and injection. The mapping sub-system can include the additional tracing logic in the DUT prior to the partitioning or in partitions after the partitioning. The design synthesizer sub-system can include the additional tracing logic in an HDL description of the DUT prior to synthesizing the HDL description.

The mapping sub-system maps each partition of the DUT to an FPGA of the emulator. For partitioning and mapping, the mapping sub-system uses design rules, design constraints (e.g., timing or logic constraints), and information about the emulator. For components of the DUT, the mapping sub-system stores information in the storage sub-system describing which FPGAs are to emulate each component.

Using the partitioning and the mapping, the mapping sub-system generates one or more bit files that describe the created partitions and the mapping of logic to each FPGA of the emulator. The bit files can include additional information such as constraints of the DUT and routing information of connections between FPGAs and connections within each FPGA. The mapping sub-system can generate a bit file for each partition of the DUT and can store the bit file in the storage sub-system. Upon request from a circuit designer, the mapping sub-system transmits the bit files to the emulator, and the emulator can use the bit files to structure the FPGAs to emulate the DUT.

If the emulator includes specialized ASICs that include the trace and injection logic, the mapping sub-system can generate a specific structure that connects the specialized ASICs to the DUT. In some embodiments, the mapping sub-system can save the information of the traced/injected signal and where the information is stored on the specialized ASIC.

The run time sub-system controls emulations performed by the emulator. The run time sub-system can cause the emulator to start or stop executing an emulation. Additionally, the run time sub-system can provide input signals and data to the emulator. The input signals can be provided directly to the emulator through the connection or indirectly through other input signal devices. For example, the host system can control an input signal device to provide the input signals to the emulator. The input signal device can be, for example, a test board (directly or through cables), signal generator, another emulator, or another host system.

The results sub-system processes emulation results generated by the emulator. During emulation and/or after completing the emulation, the results sub-system receives emulation results from the emulator generated during the emulation. The emulation results include signals traced during the emulation. Specifically, the emulation results include interface signals traced by the trace and injection logic emulated by each FPGA and can include signals traced by additional logic included in the DUT. Each traced signal can span multiple cycles of the emulation. A traced signal includes multiple states and each state is associated with a time of the emulation. The results sub-system stores the traced signals in the storage sub-system. For each stored signal, the results sub-system can store information indicating which FPGA generated the traced signal.

The debug sub-system allows circuit designers to debug DUT components. After the emulator has emulated a DUT and the results sub-system has received the interface signals traced by the trace and injection logic during the emulation, a circuit designer can request to debug a component of the DUT by re-emulating the component for a specific time period. In a request to debug a component, the circuit designer identifies the component and indicates a time period of the emulation to debug. The circuit designer's request can include a sampling rate that indicates how often states of debugged components should be saved by logic that traces signals.

The debug sub-system identifies one or more FPGAs of the emulator that are emulating the component using the information stored by the mapping sub-system in the storage sub-system. For each identified FPGA, the debug sub-system retrieves, from the storage sub-system, interface signals traced by the trace and injection logic of the FPGA during the time period indicated by the circuit designer. For example, the debug sub-system retrieves states traced by the trace and injection logic that are associated with the time period.

The debug sub-system transmits the retrieved interface signals to the emulator. The debug sub-system instructs the debug sub-system to use the identified FPGAs and for the trace and injection logic of each identified FPGA to inject its respective traced signals into logic of the FPGA to re-emulate the component for the requested time period. The debug sub-system can further transmit the sampling rate provided by the circuit designer to the emulator so that the tracing logic traces states at the proper intervals.

To debug the component, the emulator can use the FPGAs to which the component has been mapped. Additionally, the re-emulation of the component can be performed at any point specified by the circuit designer.

For an identified FPGA, the debug sub-system can transmit instructions to the emulator to load multiple emulator FPGAs with the same configuration of the identified FPGA. The debug sub-system additionally signals the emulator to use the multiple FPGAs in parallel. Each FPGA from the multiple FPGAs is used with a different time window of the interface signals to generate a larger time window in a shorter amount of time. For example, the identified FPGA can require an hour or more to use a certain amount of cycles. However, if multiple FPGAs have the same data and structure of the identified FPGA and each of these FPGAs runs a subset of the cycles, the emulator can require a few minutes for the FPGAs to collectively use all the cycles.

A circuit designer can identify a hierarchy or a list of DUT signals to re-emulate. To enable this, the debug sub-system determines the FPGA needed to emulate the hierarchy or list of signals, retrieves the necessary interface signals, and transmits the retrieved interface signals to the emulator for re-emulation. Thus, a circuit designer can identify any element (e.g., component, device, or signal) of the DUT to debug/re-emulate.

The waveform sub-system generates waveforms using the traced signals. If a circuit designer requests to view a waveform of a signal traced during an emulation run, the host system retrieves the signal from the storage sub-system. The waveform sub-system displays a plot of the signal. For one or more signals, when the signals are received from the emulator, the waveform sub-system can automatically generate the plots of the signals.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

FIG. 11 illustrates an example machine of a computer system 1100 within which a set of instructions, for causing the machine to perform any one or more of the methodologies discussed herein, may be executed. In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 1100 includes a processing device 1102, a main memory 1104 (e.g., read-only memory (ROM), flash memory, dynamic random access memory (DRAM) such as synchronous DRAM (SDRAM), a static memory 906 (e.g., flash memory, static random access memory (SRAM), etc.), and a data storage device 1118, which communicate with each other via a bus 930.

Processing device 1102 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 1102 may also be one or more special-purpose processing devices such as an application specific integrated circuit (ASIC), a field programmable gate array (FPGA), a digital signal processor (DSP), network processor, or the like. The processing device 1102 may be configured to execute instructions 1126 for performing the operations and steps described herein.

The computer system 1100 may further include a network interface device 1108 to communicate over the network 1120. The computer system 1100 also may include a video display unit 1110 (e.g., a liquid crystal display (LCD) or a cathode ray tube (CRT)), an alphanumeric input device 1112 (e.g., a keyboard), a cursor control device 1114 (e.g., a mouse), a graphics processing unit 1122, a signal generation device 1116 (e.g., a speaker), graphics processing unit 1122, video processing unit 1128, and audio processing unit 1132.

The data storage device 1118 may include a machine-readable storage medium 1124 (also known as a non-transitory computer-readable medium) on which is stored one or more sets of instructions 1126 or software embodying any one or more of the methodologies or functions described herein. The instructions 1126 may also reside, completely or at least partially, within the main memory 1104 and/or within the processing device 1102 during execution thereof by the computer system 1100, the main memory 1104 and the processing device 1102 also constituting machine-readable storage media.

In some implementations, the instructions 1126 include instructions to implement functionality corresponding to the present disclosure. While the machine-readable storage medium 1124 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine and the processing device 1102 to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electrical or magnetic signals capable of being stored, combined, compared, and otherwise manipulated. Such signals may be referred to as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

1. A method of generating waveforms associated with signals of a circuit design in a hardware emulation system, the method comprising:
capturing, using at least a first logic block disposed in the hardware emulation system, values of input signals of the circuit design at each k*d emulation cycle, wherein k and d are integers and wherein k≥0 and d>0;
capturing, using the at least first logic block and at each (k*d+i) emulation cycle, value of each input signal whose value is determined to have changed relative to the signal's value at a previous emulation cycle, wherein 0<i<d;
capturing, using at least a second logic block disposed in the hardware emulation system, output values of a plurality of sequential elements of the circuit design at each k*w*d emulation cycle, wherein w is an integer greater than zero;
capturing, using the at least second logic block and at each (k*w*d+j*d) emulation cycle, output value of each sequential element that is determined to have changed relative to the sequential element's output value at cycle (k*w*d+(j−1)*d), wherein j is an integer and wherein 0<j<w; and
generating, by a processing device, waveforms for the signals of the circuit design based on the captured values of the input signals and captured values of the plurality of sequential elements.

2. The method of claim 1, further comprising varying one or more of d and w during the hardware emulation.

3. The method of claim 1, wherein addresses associated with the input signals and the plurality of sequential elements are defined by a compiler of the hardware emulation system.

4. The method of claim 1, wherein the values of the input signals and the values of outputs of the plurality of sequential elements are streamed by a runtime software executed by a computer coupled to the hardware emulation system.

5. The method of claim 1, wherein the at least first logic block and the at least second logic block are logic blocks of one or more field programmable gate arrays (FPGAs) disposed in the hardware emulation system.

6. The method of claim 4, wherein the runtime software generates a first thread for capturing the input signals, and a second thread for capturing the output values of the plurality of sequential elements.

7. The method of claim 6, wherein synchronization between the first thread and the second thread is achieved by a clock signal controlled by the second thread.

8. The method of claim 1, wherein w has a same value as a register width of a processing unit performing the computer simulation.

9. A non-transitory computer readable medium comprising stored instructions, which when executed by a processor, cause the processor to:
receive a netlist of a logic circuit design;
program a hardware emulation system in accordance with the received netlist;
apply a testbench to the logic circuit design programmed in the hardware emulation system;
spawn, at an emulation runtime, a first thread dedicated to capturing output values of a plurality of sequential elements associated with the circuit design;
spawn, at the emulation runtime, a second thread dedicated to capturing a plurality of input signal values associated with the circuit design;
synchronize the first and second threads using a clock signal controlled by the first thread;
store the captured values of the plurality of sequential elements and input signals using the clock signal; and
generate a plurality of waveforms associated with the logic circuit design using the stored values.

10. The non-transitory computer readable medium of claim 9, wherein the stored instructions further cause the processor to:
vary, during the emulation, cycles during which the plurality of input signals are captured.

11. The non-transitory computer readable medium of claim 10, wherein the stored instructions further cause the processor to:
vary, during the emulation, cycles during which the output signals of the plurality of sequential elements are captured.

12. The non-transitory computer readable medium of claim 11, wherein the stored instructions further cause the processor to:
capture values of input signals of the circuit design at each k*d emulation cycle, wherein k and d are integers and wherein k≥0 and d>0;
capture values of each input signal whose value is determined to have changed at each (k*d+i) emulation cycle relative to the signal's value at a previous emulation cycle wherein 0<i<d;
capture output values of the plurality of sequential elements of the circuit design at each k*w*d emulation cycle, wherein w is an integer greater than zero; and
capture at each (k*w*d+j*d) emulation cycle, output value of each sequential element that is determined to have changed relative to the sequential element's output value at cycle (k*w*d+(j−1)*d), wherein j is an integer and wherein 0<j<w.

13. A hardware emulation system comprising:
a memory storing instructions; and
a processor, coupled with the memory and configured to execute the instructions, the instructions when executed causing the processor to:
capture, using at least a first logic block disposed in the hardware emulation system, values of input signals of the circuit design at each k*d emulation cycle, wherein k and d are integers, and wherein k≥0 and d>0;
capture, using the at least first logic block and at each (k*d+i) emulation cycle, values of each input signal whose value is determined to have changed relative to the signal's value at a previous emulation cycle wherein 0<i<d;
capture, using at least a second logic block disposed in the hardware emulation system, output values of a plurality of sequential elements of the circuit design at each k*w*d emulation cycle, wherein w is an integer greater than zero;
capture, using the at least second logic block and at each (k*w*d+j*d) emulation cycle, output value of each sequential element that is determined to have changed relative to the sequential element's output value at cycle (k*w*d+(j−1)*d), wherein j is an integer and wherein 0<j<w; and
invoke a computer simulation using the captured values of the input signals and captured values of the plurality of sequential elements to generate waveforms for the signals of the circuit design.

14. The hardware emulation system of claim 13, wherein the instruction further cause the processor to vary d and w during the hardware emulation.

15. The hardware emulation system of claim 13, wherein the instruction further cause the processor to invoke a compiler of the hardware emulation system to define addresses associated with the input signals and the plurality of sequential elements.

16. The hardware emulation system of claim 13, wherein the instruction further cause the processor to invoke a runtime software of the hardware emulation system to stream values of the input signals and the values of outputs of the plurality of sequential elements.

17. The hardware emulation system of claim 13, wherein the at least first logic block and the at least second logic block are logic blocks of one or more field programmable gate arrays (FPGAs) disposed in the hardware emulation system.

18. The hardware emulation system of claim 16, wherein the instruction further cause the processor to invoke the runtime software to generate a first thread for capturing the input signals, and a second thread for capturing the output values of the plurality of sequential elements.

19. The hardware emulation system of claim 18, wherein the instruction further cause the processor to achieve synchronization between the first thread and the second thread via a clock signal controlled by the second thread.

20. The hardware emulation system of claim 13, wherein w has a same value as a register width of a processor unit performing the computer simulation.
